(19) United States
(12) Patent Application Publication
(10) Pub. No.: US 2025/0299908 A1
(43) Pub. Date: Sep. 25, 2025

(54) ION IMPLANTER

(71) Applicant: NISSIN ION EQUIPMENT CO., LTD., Koka-city (JP)

(72) Inventor: Takumi SATO, Koka-city (JP)

(73) Assignee: NISSIN ION EQUIPMENT CO., LTD., Koka-city (JP)

(21) Appl. No.: 18/988,035

(22) Filed: Dec. 19, 2024

(30) Foreign Application Priority Data
Mar. 22, 2024 (JP) 2024-046624

(51) Int. Cl. H01J 37/16; H01J 37/18; H01J 37/244; H01J 37/317

(52) U.S. Cl. CPC H01J 37/165; H01J 37/185; H01J 37/244; H01J 37/3171; H01J 2237/31701

(57) ABSTRACT

An ion implanter for implanting ions into a substrate includes a transfer chamber that receives the substrate from and delivers the substrate to an outside of the ion implanter, an X-ray irradiator disposed in the transfer chamber that irradiates the substrate with X-rays before ion implantation, and a controller that stops X-ray irradiation by the X-ray irradiator or disables activation of the X-ray irradiator in response to a predetermined situation being detected in the transfer chamber or outside the transfer chamber.

### CROSS-REFERENCE TO RELATED APPLICATION

This application claims priority to Japanese Application No. 2024-046624, filed in the Japan Patent Office on Mar. 22, 2024, the disclosure of which being incorporated by reference herein in its entirety.

### BACKGROUND

### 1. Field

Various embodiments are related an ion implanter.

### 2. Description of Related Art

Some types of ion implanters include a crystal axis measuring device that irradiates a substrate with X-rays before ion implantation and measures the direction of a crystal axis of the substrate. These ion implanters can implant ions into a substrate under a condition in which channeling occurs by adjusting a irradiation direction of an ion beam with respect to the substrate based on the crystal axis measured by the crystal axis measurement device.

Channeling is a phenomenon in which, when a single crystal having a regular atomic arrangement is irradiated with an ion beam along a gap between the atomic rows of atoms, ions enter the inside of the crystal without colliding with the atoms and reach a deeper portion of the substrate.

### SUMMARY

According to an aspect of one or more embodiments, there is provided an ion implanter for implanting ions into a substrate, the ion implanter comprising a transfer chamber configured to receive the substrate from and deliver the substrate to an outside of the ion implanter; an X-ray irradiator disposed in the transfer chamber and configured to irradiate the substrate with X-rays before ion implantation; and a controller configured to stop X-ray irradiation by the X-ray irradiator or disable activation of the X-ray irradiator in response to a predetermined situation being detected in the transfer chamber or outside the transfer chamber

According to another aspect of one or more embodiments, there is provided an ion implanter comprising a transfer chamber comprising a plurality of shielding walls, at least one of the plurality of shielding walls comprising at least one shielding door; a door sensor configured to detect an open state of the at least one shielding door; an X-ray irradiator disposed in the transfer chamber and configured to irradiate a substrate with X-rays before ion implantation; and a controller. The plurality of shielding walls and the at least one shielding door are configured to shield the X-rays irradiated by the X-ray irradiator, and the controller is configured to stop X-ray irradiation by the X-ray irradiator or disable activation of the X-ray irradiator in response to the door sensor detecting the open state of the at least one shielding door.

### BRIEF DESCRIPTION OF THE DRAWINGS

The above and/or other aspects will become apparent and more readily appreciated from the following description of various embodiments, taken in conjunction with the accompanying drawings, in which:

FIG. 1 is a schematic plan view of an ion implanter in a state in which a first shielding door is closed, according to some embodiments;

FIG. 2 is a schematic plan view of an ion implanter in a state in which a first shielding door is opened, according to some embodiments;

FIG. 3 is a perspective view of an ion implanter, according to some embodiments;

FIG. 4 is a plan view of an ion implanter in a state in which a second shielding door is opened, according to some embodiments; and

FIG. 5 is a perspective view of an ion implanter, according to some embodiments.

### DETAILED DESCRIPTION

Various embodiments will be described below with reference to the drawings.

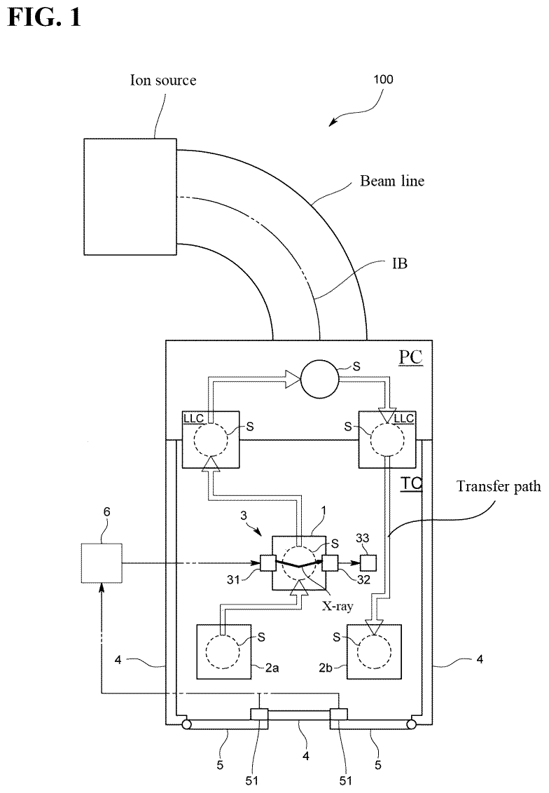

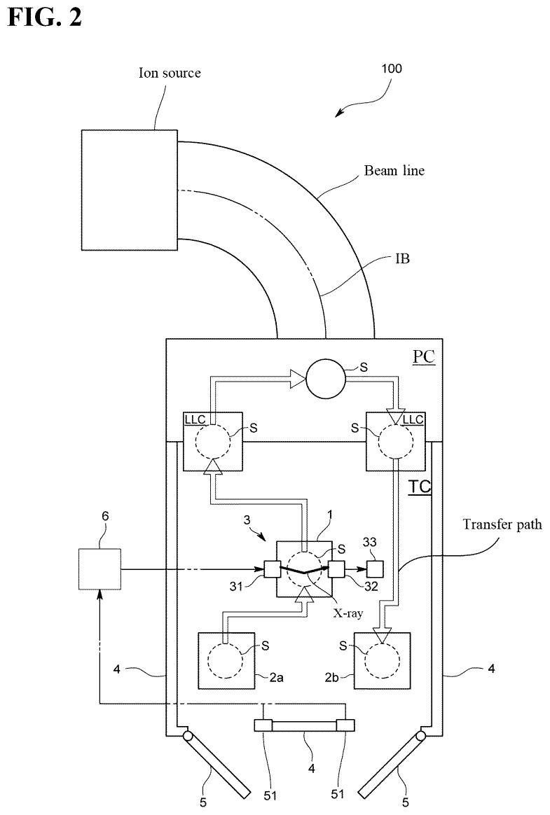

FIG. 1 is a schematic plan view of an ion implanter 100, according to some embodiments. FIG. 1 shows a state in which first shielding doors 5 are closed. FIG. 2 is a schematic plan view of the ion implanter 100. FIG. 2 shows a state where the first shielding doors 5 are opened, according to some embodiments. The ion implanter 100 is used in a semiconductor manufacturing process as an example.

As shown in FIGS. 1 and 2, the ion implanter 100 includes a process chamber PC which is evacuated to have a high vacuum environment therein. The ion implanter 100 performs ion implantation on a substrate S by irradiating the substrate S with an ion beam IB in the process chamber PC. The ion implanter 100 can perform channeling implantation in which ions reach a deeper portion of the substrate S by irradiating the substrate S with the ion beam IB along the crystal axis of the substrate S.

The substrate S may have a single crystal structure. In an embodiment, the substrate S may be, for example, a silicon wafer or a silicon carbide wafer. The substrate S may have a single-crystal film of silicon, silicon carbide, or the like formed on the surface of a base material.

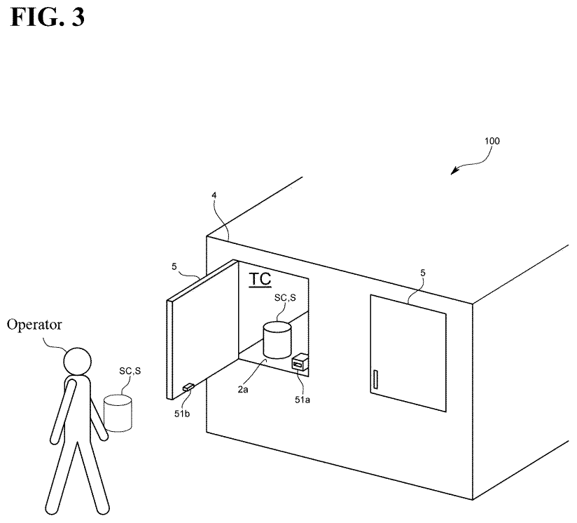

FIG. 3 is a perspective view of the ion implanter 100, according to some embodiments. As shown in FIGS. 1 to 3, the ion implanter 100 includes the process chamber PC in which the ion implantation into the substrate S is performed, and a transfer chamber TC provided adjacent to the process chamber PC. In the transfer chamber TC, the substrate S is transferred to and from the outside of the ion implanter 100. The transfer chamber TC is placed under an atmospheric pressure environment.

In an embodiment, the ion implanter 100 includes two load lock chambers LLC provided between the process chamber PC and the transfer chamber TC. The load lock chamber LLC can be evacuated to a high vacuum environment. The load lock chamber LLC can be set to an atmospheric pressure environment by introducing a gas such as nitrogen gas or dry air into the load lock chamber LLC. Thus, according to an embodiment, the load lock chamber LLC may be used to move a substrate S from the atmospheric pressure environment of the transfer chamber TC to the high vacuum environment of the process chamber PC, and vice versa.

The process chamber PC and the transfer chamber TC are connected to each other via the load lock chamber LLC so that the substrate S can be transferred therebetween. The process chamber PC and the transfer chamber TC together may constitute an end station. In some embodiments, the process chamber PC and the transfer chamber TC may not necessarily be adjacent to each other. In some embodiments, the process chamber PC and the transfer chamber TC may be connected to each other by a transfer path of the substrate S passing through the load lock chamber LLC.

As shown in FIGS. 1 and 2, the transfer chamber TC is provided with a transfer structure (not shown) provided along a predetermined transfer path of the substrate S and an aligner 1 provided on the transfer path. The aligner 1 positions the substrate S based on an orientation flat or a notch formed on the substrate S.

In an embodiment, the transfer structure may be configured by a robot that transfers the substrate S inside the transfer chamber TC. The transfer structure transfers the substrate S before ion implantation from a substrate setting part 2a provided inside the transfer chamber TC to the aligner 1, and transfers the substrate S from the aligner 1 to a load lock chamber LLC connected to the process chamber PC.

The substrate setting part 2a is a place for supplying the substrate S to the ion implanter 100. The substrate setting part 2a is a place in which a worker sets a cassette SC which is a case storing a plurality of substrates S.

The transfer structure may unload the substrate S after ion implantation into the substrate collecting part 2b provided in the transfer chamber TC via the load lock chamber LLC.

The substrate collecting part 2b is a place from which an operator collects the cassette SC storing the substrate S after ion implantation. In an embodiment, the substrate setting part 2a and the substrate collecting part 2b may be provided at different places, but embodiments are not limited thereto, and in some embodiments, the substrate setting part 2a and the substrate collecting part 2b may be provided together at a same location in the transfer chamber TC.

The ion implanter 100 further includes a crystal structure analysis device 3 that analyzes the crystal structure (e.g., a crystal orientation) of the substrate S before ion implantation.

As shown in FIGS. 1 and 2, the crystal structure analysis device 3 is disposed in the transfer chamber TC. The crystal structure analysis device 3 measures the crystal orientation of the substrate S before ion implantation or measures the crystal orientation of a thin film formed on the surface of the substrate S before ion implantation.

The crystal structure analysis devices 3 includes an X-ray irradiator 31, an X-ray detector 32, and an analyzer 33. The X-ray irradiator 31 irradiates the surface to be processed of the substrate S with X-rays. The X-ray detector 32 detects the X-ray reflected by the surface of the substrate S that is to be processed. The analyzer 33 analyzes the crystal structure of the substrate S from the information detected by the X-ray detector 32. In the embodiment illustrated in FIGS. 1-3, the crystal structure analysis device 3 is disposed in the aligner 1.

The crystal structure analysis device 3 irradiates the substrate S with X-rays to calculate the crystal orientation after the aligner 1 orients the substrate S in a specific direction with reference to the orientation flat or the notch. Based on the calculated crystal orientation, the ion implanter 100 adjusts an irradiation angle formed by the irradiation direction of the ion beam IB and the direction of the crystal axis of the substrate S, and performs the channeling implantation.

The crystal structure analysis device 3 analyzes the crystal structure of the substrate S based on the same principle as an X-ray diffractometer (XRD). Components or configurations in an X-ray diffractometer (XRD) are adopted for the X-ray irradiator 31, the X-ray detector 32, and the analyzer 33.

The analyzer 33 is physically configured by a central processing unit (CPU), a memory, an analog to digital (A/D) converter, and the like, and the CPU and peripheral devices cooperate in accordance with a program stored in a predetermined area of the memory, thereby exerting its function

In consideration of safety against X-rays, it is advantageous that the X-ray irradiator 31 reliably stops emitting X-rays while an operator loads the cassette SC containing the substrates S before ion implantation into the transfer chamber TC and while the operator unloads the cassette SC containing the substrates S after ion implantation from the transfer chamber TC. In the ion implanter 100, it is advantageous that the X-rays emitted from the X-ray irradiator 31 are prevented from leaking to the outside of the transfer chamber TC. Therefore, the ion implanter 100 has a shielding structure for physically shielding the X-rays which are about to leak to the outside of the apparatus, and a function for reliably stopping the irradiation of the X-rays when the operator carries in and out the cassette SC or performs the maintenance work or the like of the inside of the transfer chamber TC.

The transfer chamber TC is formed by shielding walls 4 having a function of shielding X-rays. The shielding wall 4 may be formed of an X-ray shielding material itself, or may have an X-ray shielding material on the surface or inside thereof.

The shielding wall 4 shields X-rays from the X-ray irradiator 31 provided in the transfer chamber TC to the outside of the transfer chamber TC and the ion implanter 100. As shown in FIGS. 1 to 3, the shielding wall 4 is provided to surround the transfer chamber TC and constitutes at least a side wall of the transfer chamber TC. In an embodiment, the shielding wall 4 may constitute an upper wall or a lower wall of the transfer chamber TC in addition to the side wall.

The configuration (e.g., a number and an arrangement) of the shielding walls 4 is not limited to the above configuration. In an embodiment, the shielding wall 4 may be configured to prevent the X-rays generated from the X-ray irradiator 31 from leaking to the outside of the ion implanter 100.

As shown in FIGS. 1 to 3, first shielding doors 5 for opening and closing the transfer chamber TC are provided in the shielding wall 4. In an embodiment, the first shielding door 5 may be a hinged door formed of a plate made of an X-ray shielding material. In some embodiments, the shielding wall 4 may be provided with two first shielding doors 5, and the two first shielding doors 5 may be disposed on the front surfaces of the substrate setting part 2a and the substrate collecting part 2b, respectively. In other words, in some embodiments, one of the first shielding doors 5 may be disposed on the front surface of the substrate setting part 2a and another of the first shielding doors 5 may be disposed on the front surface of the substrate collecting part 2b. In a state in which the first shielding door 5 is opened, the operator can perform an operation of setting the cassette SC in the substrate setting part 2a and an operation of collecting the cassette SC from the substrate collecting part 2b. The number and arrangement of the first shielding doors 5 are not limited to the configuration illustrated in FIGS. 1-3.

The ion implanter 100 may include a first door sensor 51 that detects an open/closed state of the first shielding door 5. The first door sensor 51 outputs a detection signal indicating that the first door sensor 51 detects the open state to a controller 6 described later, for example, in a state in which the first shielding door 5 is opened. In an embodiment, the first door sensor 51 may be a safety door switch configured by a main body 51a fixed to the opening portion of the first shielding door 5 and an operation part 51b fixed to the inner side of the first shielding door 5.

In an embodiment, the operation part 51b may be inserted into the main body 51a in a state in which the first shielding door 5 is closed. In the state in which the operation part 51b is inserted into the main body 51a, the main body 51a detects the closed state of the first shielding door 5 by the switch provided inside the main body portion 51b being pressed and closed by the operation portion 51a.

In a state in which the first shielding door 5 is opened, the operation part 51b is removed from the main body 51a. In this way, in the state in which the operation part 51b is separated from the main body 51a, the main body 51a detects the open state of the first shielding door 5 by opening the contact-point switch.

As the first door sensor 51, in some embodiments, a limit switch in which the door operates a switch as an actuator, a non-contact proximity sensor in which a contact of the switch is operated by magnetism or the like, or the like can be used. In some embodiments, the first door sensor 51 may be a camera or the like.

As shown in FIGS. 1 and 2, in some embodiments, the ion implanter 100 may include a controller 6 that performs interlock control for stopping the X-ray irradiation by the X-ray irradiator 31 or disabling the activation of the X-ray irradiator 31 when a predetermined situation is detected in the transfer chamber TC or outside the transfer chamber TC. In each drawing, the controller 6 is illustrated as being disposed outside the apparatus for convenience, but embodiments are not limited thereto and, in some embodiments, the controller 6 may be provided inside the ion implanter 100.

The predetermined situation refers to, for example, a situation in which an operator who supplies the substrate S to the ion implanter 100 opens the first shielding door 5 or a second shielding door 7 to be described later, or a situation in which the operator enters a predetermined area outside the transfer chamber TC.

In an embodiment, the controller 6 may detect a state in which the first shielding door 5 is opened as the predetermined situation as shown in FIGS. 2 and 3. More specifically, in an embodiment, when the first door sensor 51 detects that the first shielding door 5 is opened, the controller 6 transmits a stop command signal for commanding to stop the irradiation of X-rays from the X-ray irradiator 31 or a start disable command signal for commanding to disable the start of the X-ray irradiator 31 to the crystal structure analysis device 3. The controller 6 may transmit both the stop command signal and the start disable command signal to the crystal structure analysis device 3.

The controller 6 may be physically configured by a CPU, a memory, an A/D converter, and the like, and the CPU and peripheral devices may cooperate in accordance with a program stored in an area of the memory, and access the area of the memory to execute the program to cause the CPU to execute the interlock control. In the embodiment illustrated in FIGS. 1-3, the controller 6 is provided in the transfer chamber TC.

The interlock control of the crystal structure analysis device 3 by the controller 6 will be described in detail separately for the case in which the X-ray is irradiated from the crystal structure analysis device 3 and the case where the X-ray is not irradiated.

In a case in which the substrate S is irradiated with X-rays in the transfer chamber TC, for example, when an operator opens the first shielding door 5 to supply or collect the substrate S, the controller 6 stops the irradiation of X-rays from the X-ray irradiator 31. Thereafter, when the first shielding door 5 is closed, the controller 6 automatically restarts the irradiation of X-rays from the X-ray irradiator 31. The emission of X-rays from the X-ray irradiator 31 may be resumed when a predetermined instruction is received from the operator after the first shielding door 5 is closed.

In a case in which the substrate S is not irradiated with the X-rays in the transfer chamber TC, for example, when the operator opens the first shielding door 5 to supply or collect the substrate S, the controller 6 disables the activation of the X-ray irradiator 31. Thereafter, when the first shielding door 5 is closed, the controller 6 enables the X-ray irradiator 31 to be activated.

According to the ion implanter 100, since X-rays are not irradiated by the interlock control in a predetermined situation (for example, a situation in which the first shielding door 5 is opened), an operator who performs an operation such as the supply of the substrate S can safely perform the operation. According to the ion implanter 100, when the first shielding door 5 is not completely closed or when the operator forgets to close the first shielding door 5, the irradiation of X-rays is not started. Therefore, a situation in which the X-rays generated from the X-ray irradiator 31 leak to the outside of the transfer chamber TC after the work is prevented.

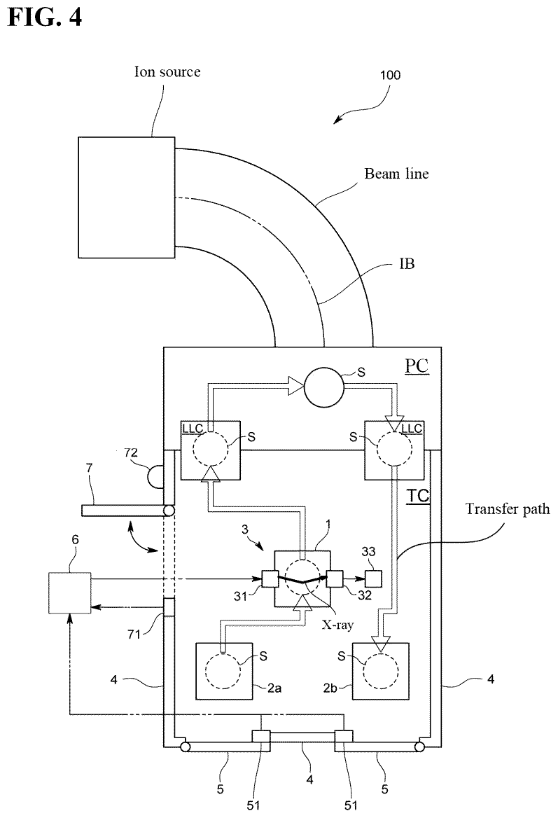

FIG. 4 is a plan view of an ion implanter 100 according to some embodiments. FIG. 4 shows a state in which a second shielding door 7 is opened. The ion implanter 100 may further include the second shielding door 7 provided on a side surface of the transfer chamber TC and a second door sensor 71 configured to detect an open/closed state of the second shielding door 7, as illustrated in FIG. 4. In an embodiment, the second shielding door 7 may be formed of a plate made of an X-ray shielding material, as in the case of the first shielding door 5. In an embodiment, the second door sensor 71 may be a safety door switch, as with the first door sensor 51.

The second shielding door 7 may be a door provided for an operator to perform maintenance, inspection, or the like of the inside of the transfer chamber TC. When the second shielding door 7 is opened, the operator can access the devices provided in the transfer chamber TC from the outside of the transfer chamber TC. The second shielding door 7 is disposed at a position at which the operator can access the X-ray irradiator 31 or the X-ray detector 32. The second shielding door 7 may be a door for inspection provided inside the transfer chamber TC. The second shielding door 7 may be disposed so as to be accessible to a device other than the crystal structure analysis device 3 via the second shielding door 7.

When the second shielding door 7 is opened, the operator can inspect, maintain, and repair the devices provided in the transfer chamber TC. While the second shielding door 7 is opened, the crystal structure analysis device 3 is interlocked, and thus the generation of X-rays from the X-ray irradiator 31 is reliably stopped. Therefore, the worker can safely perform work such as inspection.

The ion implanter 100 may include a human detection sensor 72 disposed in the vicinity of the second shielding door 7 of the shielding wall 4 as illustrated in FIG. 4. The human detection sensor 72 detects a situation in which a person enters a predetermined area set around the outside of the transfer chamber TC as unfavorable situation. The controller 6 may perform control to stop the X-ray irradiator 31 or control to disable the activation of the X-ray irradiator 31 based on the output of the human detection sensor 72. In an embodiment, the human detection sensor 72 may be, for example, an infrared sensor using a PIR or the like attached to the outside of the shielding wall 4. In an embodiment, the human detection sensor 72 may be another infrared sensor, an ultrasonic sensor, a microwave sensor, a sound sensor, or the like. In an embodiment, the human detection sensor may be disposed near the first shielding door 5.

With such a configuration, the X-ray irradiation can be stopped by the interlock control at a stage when the operator approaches the second shielding door 7, that is, at a stage earlier than the operator opens the second shielding door 7.

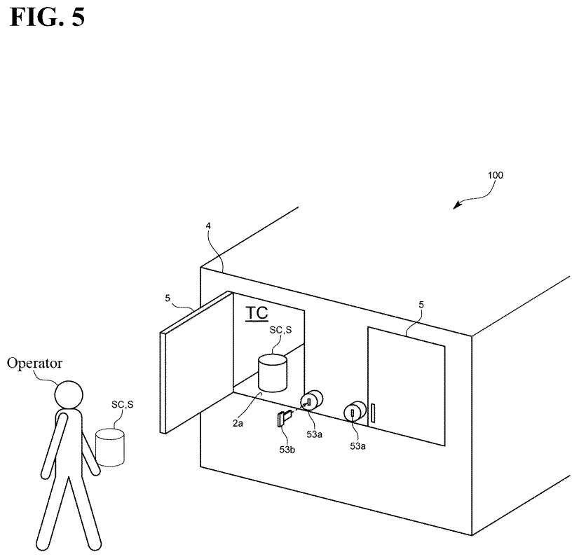

FIG. 5 is a perspective view of an ion implanter 100, according to some embodiments. As shown in FIG. 5, the ion implanter 100 may include a door lock 53 that locks and unlocks the first shielding door 5. The door lock 53 may lock and unlock the second shielding door 7. In an embodiment, the door lock 53 may include a locking main body 53a fixed to the shielding wall 4 and a key 53b. The first shielding door 5 is unlocked by inserting the key 53b into the opening of the locking main body 53a by an operator. The first shielding door 5 is locked by the operator pulling out the key 53b from the opening of the locking main body 53a.

Although FIG. 5 shows a configuration in which the door lock 53 is provided instead of the first door sensor 51, in some embodiments, the door lock 53 may be provided together with the first door sensor 51. In some embodiments, the first door sensor 51 or the second door sensor 71 may have a function of locking and unlocking the first shielding door 5 or the second shielding door 7, respectively.

In an embodiment, the controller 6 may detect a state in which the door lock 53 is unlocked or unlocked as the predetermined situation in addition to or instead of the state where the first shielding door 5 or the second shielding door 7 is opened.

In an embodiment, for example, when an operator unlocks the locked first shielding door 5, the controller 6 performs interlock control to stop the X-ray irradiation from the X-ray irradiator 31. In the unlocked state, even if an operator opens and closes the first shielding door 5, the lock by the controller 6 remains applied, and thereafter, when the first shielding door 5 is locked, the interlock is released from the controller 6. In this case, the interlock is activated before the operator actually opens the first shielding door 5. Therefore, when the operator carries in and out the cassette SC, the irradiation of X-rays from the X-ray irradiator 31 can be reliably stopped.

In an embodiment, the controller 6 may cause the door lock 53 to lock the first shielding door 5 or the second shielding door 7 when the X-ray irradiator 31 is irradiating X-rays. In this case, the first shielding door 5 or the second shielding door 7 is not opened during the irradiation of X-rays.

In some embodiments, the ion implanter 100 includes a plurality of first shielding doors 5 and the second shielding door 7 for different purposes. The controller 6 may detect a state in which at least one of the shield doors 5 and 7 is opened or unlocked as the predetermined situation.

In an embodiment, the ion implanter 100 may be configured to stop the transfer of the substrate S from the transfer chamber TC to the process chamber PC when the controller 6 stops the irradiation of the X-rays from the X-ray irradiator 31. This configuration and operation prevents the substrate S not irradiated with X-rays, that is, the substrate S whose crystal orientation is not measured from being transferred to the process chamber PC.

It should be understood that embodiments are not limited to the various embodiments described above, but various other changes and modifications may be made therein without departing from the spirit and scope thereof as set forth in appended claims.

What is claimed is:

1. An ion implanter for implanting ions into a substrate, the ion implanter comprising:
a transfer chamber configured to receive the substrate from and deliver the substrate to an outside of the ion implanter;
an X-ray irradiator disposed in the transfer chamber and configured to irradiate the substrate with X-rays before ion implantation; and
a controller configured to stop X-ray irradiation by the X-ray irradiator or disable activation of the X-ray irradiator in response to a predetermined situation being detected with respect to the transfer chamber or outside the transfer chamber.

2. The ion implanter as recited in claim 1, wherein the controller stops the X-ray irradiation by the X-ray irradiator or disables the activation of the X-ray irradiator in response to the predetermined situation being detected with respect to the transfer chamber,
the transfer chamber includes at least one shielding door configured to shield the X-rays from the X-ray irradiator, and
the predetermined situation comprises a state in which the at least one shielding door is opened or a state in which the at least one shielding door is not locked.

3. The ion implanter as recited in claim 2, further comprising a door sensor configured to detect an open/closed state of the at least one shielding door.

4. The ion implanter as recited in claim 2, wherein the at least one shielding door is provided on a transfer path through which the substrate is transferred from the outside to the transfer chamber.

5. The ion implanter as recited in claim 2, wherein the at least one shielding door is a door for inspection of the X-ray irradiator provided in the transfer chamber.

6. The ion implanter as recited in claim 2, further comprising a door lock that locks and unlocks the at least one shielding door.

7. The ion implanter as recited in claim 6, wherein the controller causes the door lock to lock the at least one shielding door when the X-ray irradiator is irradiating X-rays.

8. The ion implanter as recited in claim 1, wherein the controller is configured to stop the X-ray irradiation by the X-ray irradiator or disable the activation of the X-ray irradiator in response to an operator entering a predetermined area around the transfer chamber.

9. The ion implanter as recited in claim 1, further comprising a process chamber in which ions are implanted into the substrate.

10. The ion implanter as recited in claim 9, wherein the controller stops the transfer of the substrate from the transfer chamber to the process chamber when the controller stops the X-ray irradiation of the X-rays from the X-ray irradiator or disables the activation of the X-ray irradiator.

11. The ion implanter as recited in claim 1, wherein the transfer chamber is formed by shielding walls configured to shield the X-rays.

12. The ion implanter as recited in claim 11, wherein at least one of the shielding walls comprises at least one shielding door configured to shield the X-rays.

13. An ion implanter comprising:
a transfer chamber comprising a plurality of shielding walls, at least one of the plurality of shielding walls comprising at least one shielding door;
a door sensor configured to detect an open state of the at least one shielding door;
an X-ray irradiator disposed in the transfer chamber and configured to irradiate a substrate with X-rays before ion implantation; and
a controller,
wherein the plurality of shielding walls and the at least one shielding door are configured to shield the X-rays irradiated by the X-ray irradiator, and
the controller is configured to stop X-ray irradiation by the X-ray irradiator or disable activation of the X-ray irradiator in response to the door sensor detecting the open state of the at least one shielding door.

14. The ion implanter as recited in claim 13, comprising a human detection sensor,
wherein the controller is configured to stop the X-ray irradiation by the X-ray irradiator or disable the activation of the X-ray irradiator in response to the human detection sensor detecting an operator in a vicinity of the transfer chamber.

15. The ion implanter as recited in claim 13, wherein the at least one shielding door is provided on a transfer path through which the substrate is transferred from the outside to the transfer chamber.

16. The ion implanter as recited in claim 13, further comprising a door lock that locks and unlocks the at least one shielding door.

17. The ion implanter as recited in claim 16, wherein the controller controls the door lock to lock the at least one shielding door when the X-ray irradiator is irradiating X-rays.

18. The ion implanter as recited in claim 13, further comprising a process chamber in which ions are implanted into the substrate.

19. The ion implanter as recited in claim 18, wherein the controller stops the transfer of the substrate from the transfer chamber to the process chamber when the controller stops the X-ray irradiation of the X-rays from the X-ray irradiator or disables the activation of the X-ray irradiator.
